(19) United States
(12) Patent Application Publication
(10) Pub. No.: US 2024/0332898 A1
(43) Pub. Date: Oct. 3, 2024

(54) SEMICONDUCTOR LASER

(71) Applicant: Lumentum Operations LLC, San Jose, CA (US)

(72) Inventor: Atsushi NAKAMURA, Komoro (JP)

(21) Appl. No.: 18/477,446

(22) Filed: Sep. 28, 2023

(30) Foreign Application Priority Data
Mar. 30, 2023 (JP) 2023-054498
Jun. 22, 2023 (JP) 2023-102676

(51) Int. Cl. H01S 5/12; H01S 5/028; H01S 5/042

(52) U.S. Cl. CPC H01S 5/124; H01S 5/028; H01S 5/04256; H01S 5/2205; H01S 5/227; H01S 5/34

(57) ABSTRACT

To obtain both a high output power and a single mode oscillation of a semiconductor laser. The semiconductor laser includes first and second regions. In the first region, a diffraction pattern having a high reflectance with respect to a light beam having a Bragg wavelength is arranged. The second region includes: a π-shift region with a phase shifting by π from a phase of the first region, a secondary λ/4 shift portion, an in-phase region having the same phase as that of the first region, and the secondary λ/4 shift portion are arranged toward a second end portion in the stated order; and the π-shift region. The π-shift region is longer than the in-phase region, a length of the first region is larger than a difference between the π-shift region and the in-phase region, and facets on both sides each have a low-reflection facet coating film formed thereon.

### CROSS-REFERENCE TO RELATED APPLICATIONS

The present application claims priority from Japanese Patent Application number 2023-102676 filed on Jun. 22, 2023 and from Japanese Patent Application number 2023-054498 filed on Mar. 30, 2023, the contents of which are hereby incorporated by reference into this application.

### TECHNICAL FIELD

The present disclosure relates generally to a semiconductor laser.

### BACKGROUND

Semiconductor lasers can be used as a light source in optical communications. A distributed feedback semiconductor laser (DFB laser) is one type of a semiconductor laser. The DFB laser includes a diffraction grating. Further, a structure in which the diffraction grating is provided can include a phase shift portion in order to improve characteristics. When an anti-reflection film (low-reflection film) is formed on both facets of a semiconductor laser and a λ/4 shift portion is arranged in the diffraction grating, a stable single-wavelength operation can be obtained.

Further, a plurality of λ/4 shift portions are be arranged in a structure.

### SUMMARY

When low-reflection films are formed on both facets of a resonator and a λ/4 shift portion is provided at a center of the resonator, a single mode oscillation can be obtained, and for example, a side mode suppression ratio (SMSR) yield can be theoretically 100%. However, light output intensity from both facets is theoretically the same, and intensity of light output from the facets on which the low-reflection films are arranged is lower than in a case of a semiconductor laser in which facets of the resonator are formed with a high-reflection film and a low-reflection film. Meanwhile, the semiconductor laser formed through use of the low-reflection film and the high-reflection film varies in facet phase due to manufacturing variations, and hence the SMSR yield is lower than when both facets are formed with low-reflection films.

As described above, there has been a problem of achieving both a single mode oscillation (high SMSR yield) and a high power.

Some implementations described herein include a semiconductor laser that achieves both a high power and a single mode oscillation.

In some implementations, a semiconductor laser includes a substrate; an active layer formed above the substrate; a diffraction grating layer that includes a primary λ/4 phase shift portion, and includes a first region between a first end portion and the primary λ/4 phase shift portion and a second region between a second end portion on a side opposite to the first end portion and the primary λ/4 phase shift portion; a first electrode below the substrate in common to the first region and the second region; and a second electrode above the diffraction grating layer in common to the first region and the second region, wherein the first region has a diffraction pattern arranged therein, the diffraction pattern having a high reflectance with respect to a light beam having a Bragg wavelength, wherein the second region includes: a region in which a π-shift region with a phase shifting by π from a phase of the first region, a secondary λ/4 shift portion, an in-phase region having the same phase as the phase of the first region, and the secondary λ/4 shift portion are arranged toward the second end portion in the stated order; and the π-shift region arranged on the second end portion side of the region, wherein a total length of the π-shift region is longer than a total length of the in-phase region in a direction in which the diffraction grating layer extends, wherein a length of the first region is larger than a difference between the total length of the π-shift region and the total length of the in-phase region in the direction in which the diffraction grating layer extends, and wherein each of a front facet close to the second end portion and a back facet close to the first end portion has a low-reflection facet coating film formed thereon.

### BRIEF DESCRIPTION OF THE DRAWINGS

FIG. 1 is an example of a top view for illustrating a semiconductor laser according to a first example implementation of the present invention.

FIG. 2 is a schematic sectional view for illustrating the semiconductor laser of FIG. 1 taken along the line II-II.

FIG. 3 is a schematic sectional view for illustrating the semiconductor laser of FIG. 1 taken along the line III-III.

FIG. 4 is a schematic sectional view for illustrating a semiconductor laser according to Modification Example 1 of the first example implementation taken along the line II-II.

FIG. 5 is a schematic sectional view for illustrating a semiconductor laser according to Modification Example 2 of the first example implementation taken along the line II-II.

FIG. 6 is an example of a top view for illustrating a semiconductor laser according to a second example implementation of the present invention.

FIG. 7 is a schematic sectional view for illustrating the semiconductor laser of FIG. 6 taken along the line VII-VII.

FIG. 8 is an example of a top view for illustrating a semiconductor laser according to a third example implementation of the present invention.

### DETAILED DESCRIPTION

Embodiments of the present invention are specifically described in detail in the following with reference to the attached drawings. Throughout the figures for illustrating the embodiments, like reference numerals are used to represent members having like functions, and a repeated description thereof is omitted. The drawings referred to in the following are only for illustrating the embodiments by way of examples, and are not necessarily drawn to scale.

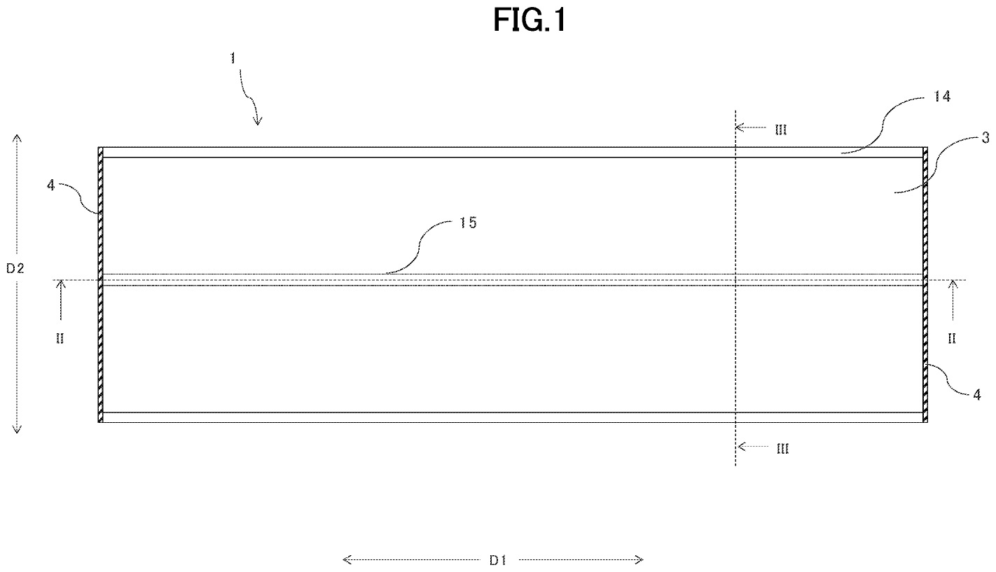

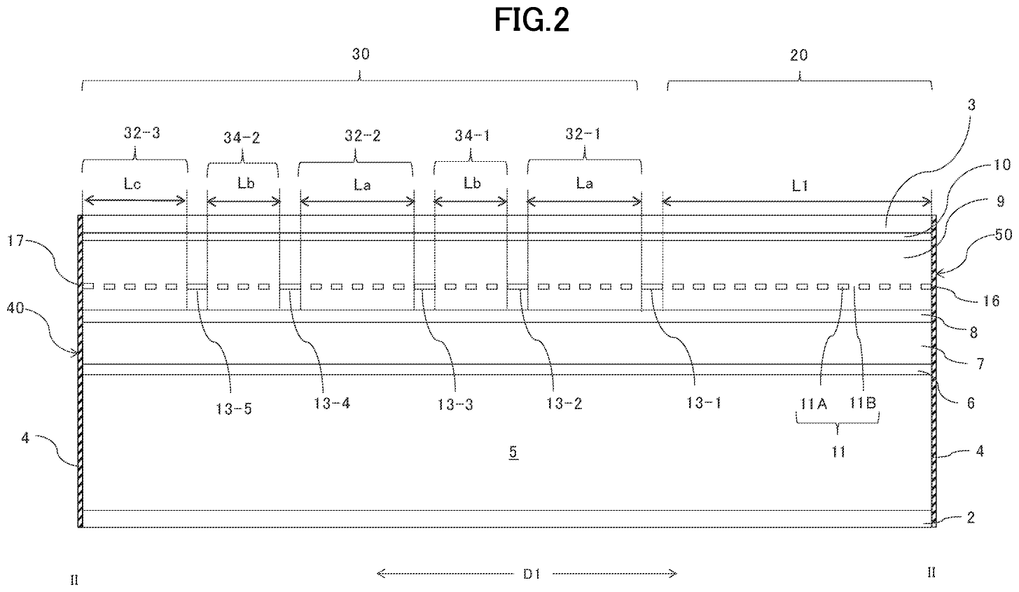

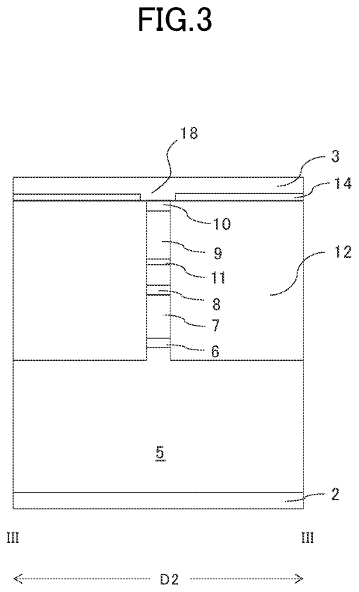

FIG. 1 is a top view for illustrating a semiconductor laser 1 according to a first example implementation of the present invention. FIG. 2 shows a schematic sectional view taken along the line II-II of FIG. 1. FIG. 3 shows a schematic sectional view taken along the line III-III of FIG. 1. The semiconductor laser 1 may include a first electrode 2 on a back surface thereof and a second electrode 3 on a front surface thereof. The first electrode 2 may be provided below a substrate 5 in common to a first region 20 (described later) and a second region 30 (described later). The second electrode 3 may be provided above a diffraction grating layer 11 (described later) in common to the first region 20 and the second region 30. The first electrode 2 and the second electrode 3 may be metal layers. A light beam may be emitted from a front facet 40 (facet on the left side of FIG. 1) through injection of a current between the first electrode 2 and the second electrode 3. A low-reflection facet coating film 4 may be formed on the front facet 40 and a back facet 50 (facet on the right side of FIG. 1).

In the semiconductor laser 1, semiconductor layers grow in the stated order of a first conductivity type optical confinement layer (SCH layer) 6, an active layer 7, a second conductivity type optical confinement layer (SCH layer) 8, a second conductivity type cladding layer 9, and a second conductivity type contact layer 10 on the substrate 5 of the first conductivity type. Further, the second conductivity type cladding layer 9 may have the diffraction grating layer 11 formed therein. The semiconductor laser 1 may be a DFB laser. The active layer 7 may be formed of, for example, a multiple-quantum well layer. Further, the multiple-quantum well layer may be an intrinsic semiconductor or an n-type semiconductor. In this case, the first conductivity type may be an n-type and the second conductivity type may be a p-type, but the first conductivity type may be the p-type and the second conductivity type may be the n-type. Further, the semiconductor layers described above may have a mesa structure 15. The mesa structure 15 may extend in a light extraction direction (first direction D1). A lower portion of the mesa structure 15 may be a part of the substrate 5. Both sides of the mesa structure 15 may be covered with a semi-insulating buried layer 12. The buried layer 12 may be a stack formed of semiconductor layers of the p-type and the n-type. The dotted line of FIG. 1 indicates a position of a boundary between an upper portion of the mesa structure 15 and the buried layer 12.

The semiconductor laser 1 may have an insulating film 14 on the front surface thereof. The insulating film 14 may cover the front surface of the semiconductor laser 1 except for a part thereof. The insulating film 14 may include an opening (through-hole) 18 in a region corresponding to the upper portion of the mesa structure 15. In the through-hole 18, the second electrode 3 and the second conductivity type contact layer 10 may be connected, and an electric signal may be applied to the mesa structure 15 (a current may be injected). Accordingly, the through-hole 18 may be formed along the first direction D1. Further, in a second direction D2 perpendicular to the first direction D1, the through-hole 18 may have a width larger than a width of the mesa structure 15. However, both may have the same width.

Specifically, the diffraction grating layer 11 may be of a floating type, and may be formed of the second conductivity type cladding layer 9 and regions having a first refractive index different from a refractive index of the second conductivity type cladding layer 9. In this case, when the refractive index of the second conductivity type cladding layer 9 is set as a second refractive index, the diffraction grating layer 11 may have a structure in which a first refractive index region 11A and a second refractive index region 11B may be alternately arranged. In this case, the first refractive index may be higher than the second refractive index. However, a relationship of the refractive indices may be reversed. The diffraction grating layer 11 may be arranged along the first direction D1. The diffraction grating layer 11 may include a plurality of phase shift portions having a partially different grating period. In this case, five phase shift portions 13 may be provided, and may all be λ/4 phase shift portions.

The diffraction grating layer 11 may have the first region 20 between a first end portion 16 and a primary λ/4 phase shift portion 13 and the second region 30 between a second end portion 17 on a side opposite to the first end portion 16 and the primary λ/4 phase shift portion 13. In the first region 20, a diffraction pattern having such a period as to exhibit a high reflectance with respect to a light beam having a Bragg wavelength may be arranged. Meanwhile, the second region 30 may include: a region in which a π-shift region 32 with a phase shifting by π from a phase of the first region 20, a secondary λ/4 shift portion 13, an in-phase region having the same phase as that of the first region 20, and the secondary λ/4 shift portion 13 may be arranged toward the second end portion 17 in the stated order; and the π-shift region 32 arranged on the second end portion 17 side of the region. Specifically, the diffraction grating layer 11 may have the first region 20 between the back facet 50 and a phase shift portion 13-1 (primary λ/4 phase shift portion) closest to the back facet 50. The first region 20 may have a length L1 in the first direction D1. The first region 20 may be formed by alternately arranging the first refractive index region 11A and the second refractive index region 11B that may have the same length in a direction in which the diffraction grating layer 11 extends. That is, a diffraction grating layer in the first region 20 may have a uniform grating structure in which the first refractive index region 11A and the second refractive index region 11B are periodically arranged. The diffraction grating layer 11 may have the second region 30 being a region between the phase shift portion 13-1 and the front facet 40. Each π-shift region of the second region 30 may be formed by alternately arranging the first refractive index region 11A and the second refractive index region 11B that may have the same length as that in the first region 20 such that the phase shifts by π from the phase of the first region 20. Meanwhile, each in-phase region of the second region 30 may be formed by alternately arranging the first refractive index region 11A and the second refractive index region 11B that may have the same length as that in the first region 20 such that the phase becomes the same as the phase of the first region 20. Specifically, the second region 30 may include a plurality of phase shift portions 13. An example in which each phase shift portion 13 included in the second region 30 and the phase shift portion arranged between the first region 20 and the second region 30 have the same material and length described below, and in order to distinguish between the two kinds of phase shift portions, the phase shift portion 13 included in the second region 30 may be also referred to as “secondary phase shift portion” (or “secondary λ/4 phase shift portion”). Each of regions other than the phase shift portions 13 may have a uniform grating structure in which the first refractive index region 11A and the second refractive index region 11B are periodically arranged, and may have the same grating period as that of the diffraction grating structure of the first region 20. In this case, the diffraction grating layer 11 may have a diffraction grating period set so as to oscillate a wavelength of a 1.3 micrometers (μm)*band or a 1.55 μm band. However, another wavelength band may be used. The phase shift portions 13 arranged from the phase shift portion 13-1 toward the front facet 40 side may be hereinafter referred to as “phase shift portions 13-2, 13-3, 13-4, and 13-5.” In the second region 30, the π-shift region in which the phase shifts by π from the phase of the diffraction grating in the first region 20 and the in-phase region in which the phase shifts by 2π may be alternately arranged. The in-phase region may have a phase that shifts by 2π from the phase of the diffraction grating in the first region 20, and thus may have the same phase as that of the diffraction grating in the first region 20. Specifically, a region sandwiched between the phase shift portion 13-1 and the phase shift portion 13-2 may be the π-shift region, and a region sandwiched between the phase shift portion 13-2 and the phase shift portion 13-3 may be the in-phase region. In the same manner, a region sandwiched between the phase shift portion 13-3 and the phase shift portion 13-4 may be the π-shift region, a region sandwiched between the phase shift portion 13-4 and the phase shift portion 13-5 may be the in-phase region, and a region sandwiched between the phase shift portion 13-5 and the front facet 40 may be the π-shift region. In other words, a first π-shift region 32-1, a first in-phase region 34-1, a second-shift region 32-2, a second in-phase region 34-2, and a third π-shift region 32-3 may be arranged from the first region 20 toward the front facet 40 in the stated order. In this case, the first π-shift region 32-1 and the second π-shift region 32-2 each may have a length La in the first direction D1, and the first in-phase region 34-1 and the second in-phase region 34-2 each may have a length Lb in the first direction D1. Further, La may be longer than Lb. The third π-shift region 32-3 may have a length Lc.

The direction along the first direction D1 may be hereinafter referred to as “forward and backward.” The forward direction may be defined as a direction toward the front facet 40. When viewed broadly, the semiconductor laser 1 may be formed of the first region 20 and the second region 30. Light beams reflected through π-shift in the second region 30 may be coupled at the Bragg wavelength of the first region 20, to thereby cause optical characteristics (e.g., single mode oscillation and light intensity) of the entire semiconductor laser 1 to be determined. In this case, the diffraction grating layer 11 may be formed over both the first region 20 and the second region 30, and the first refractive index regions 11A in the first region 20 and the second region 30 may have the same the material (same refractive index), while the second refractive index region 11B in the first region 20 and the second region 30 may have the same material (e.g., a same refractive index). Further, area ratios (duty cycles) between the first refractive index regions 11A and the second refractive index regions 11B may be the same.

When viewed from the first region 20, light beams propagated from the first region 20 may appear as reflected light beams having the phase shifted by π in the first π-shift region 32-1 of the second region 30. Further, light beams that have passed through the first π-shift region 32-1 may appear as light beams having the phase shifted by 2π in the first in-phase region 34-1, that is, light beams reflected without having the phase inverted. In this case, the light beams reflected in the first in-phase region 34-1 and the light beams reflected in the first π-shift region 32-1 may be inverted in phase, and thus cancel each other. However, due to the first π-shift region 32-1 that may be longer than the first in-phase region 34-1, not all the light beams reflected in the first π-shift region 32-1 may be canceled, and light beams reflected in a region corresponding to a difference between the lengths La and Lb return to the first region 20. That is, light beams reflected in a region of the first π-shift region 32-1 between the phase shift portion 13-2 and a position spaced backward therefrom by Lb may be canceled. This may be equivalent to a case in which, when viewed from the first region 20, the light beams may be not reflected, that is, may be transmitted. When the light beams may be not reflected, a normalized coupling coefficient κL may be regarded as zero for the Bragg wavelength of the first region 20. That is, κL may be regarded as zero for a region between positions spaced forward and backward from the phase shift portion 13-2 by Lb. Meanwhile, the region of the first π-shift region 32-1 corresponding to the difference between La and Lb may contribute to the reflection, and hence an overall normalized coupling coefficient of the first π-shift region 32-1 and the first in-phase region 34-1 may be regarded as κ×(La−Lb).

In the same manner, light beams reflected in regions of the second π-shift region 32-2 and the second in-phase region 34-2 between positions spaced forward and backward from the phase shift portion 13-4 by Lb may cancel each other. Accordingly, an overall normalized coupling coefficient of the second π-shift region 32-2 and the second in-phase region 34-2 may be κ×(La−Lb).

Further, a normalized coupling coefficient of the third π-shift region 32-3 may be κ×Lc. A normalized coupling coefficient of the entire second region 30 may be κ×(2La−2Lb+Lc). In this case, a normalized coupling coefficient of the first region 20 may be κL1, and L1 may be set such that the normalized coupling coefficient of the first region 20 is larger than the normalized coupling coefficient of the second region 30. For that reason, intensity of light output from the front facet 40 may be made higher than intensity of light output from the back facet 50. In other words, a front-to-back ratio of light output may be made higher than in a case of a semiconductor laser in which low-reflection facet coating films are formed on both facets and a λ/4 phase shift portion is arranged in the central portion.

Further, in the first example implementation, the phase shift portion 13-1 may be arranged on the back facet 50 side of the semiconductor laser 1 relative to the center of a resonator length thereof (length by which the diffraction grating layer 11 may be formed in the first direction D1). For example, when only one phase shift portion is included, it may be possible to increase light output intensity on the front side by arranging the phase shift portion on the front side. However, in a structure including a plurality of phase shift portions and having low-reflection facet coating films formed on both facets, the phase shift portion serving as a boundary between the first region and the second region may be preferred to be arranged on the back side as in the first example implementation. In order to achieve both a high power and a single mode oscillation, it may be preferred to arrange the phase shift portion 13-1 such that a length ratio between the first region 20 and the second region 30 may be from 3:7 to 9:1.

The length Lc of the third π-shift region 32-3 may be longer or shorter than La or Lb as long as the normalized coupling coefficient of the entire second region 30 is smaller than the normalized coupling coefficient of the first region 20. From the viewpoint of a single mode oscillation, Lc may be preferred to be shorter than L1. The number of phase shift portions 13 (secondary λ/4 phase shift portions) included in the second region 30 may also be freely set. Any number may be employed as long as regions in which reflected light beams cancel each other and a region in which reflected light beams remain may be provided before and after one phase shift portion 13 and the normalized coupling coefficient of the entire second region 30 may be smaller than the normalized coupling coefficient of the first region 20. The lengths La and Lb may also be freely set. Further, in FIG. 2, the phase shift portion 13 is illustrated as having a structure in which the first refractive index regions 11A may be continuously arranged, but the present invention is not limited thereto, and a structure in which two second refractive index regions 11B are continuously arranged may be employed.

The first region 20 and the second region 30 may be defined herein as starting at the facets of the semiconductor laser 1, but may be strictly defined as starting at end portions of the diffraction grating layer 11. That is, in the first example implementation, the first region 20 may be defined as extending from the end portion (first end portion 16) of the diffraction grating layer 11 on the back side to the phase shift portion 13, and the second region 30 may be defined as extending from the phase shift portion 13 to the end portion (second end portion 17) of the diffraction grating layer 11 on the front side. In the first example implementation, the end portions of the diffraction grating layer 11 may be positioned at substantially the same position as the front facet 40 or the back facet 50. Further, the diffraction grating layer 11 may be arranged below the first conductivity type SCH layer (first conductivity type optical confinement layer 6).

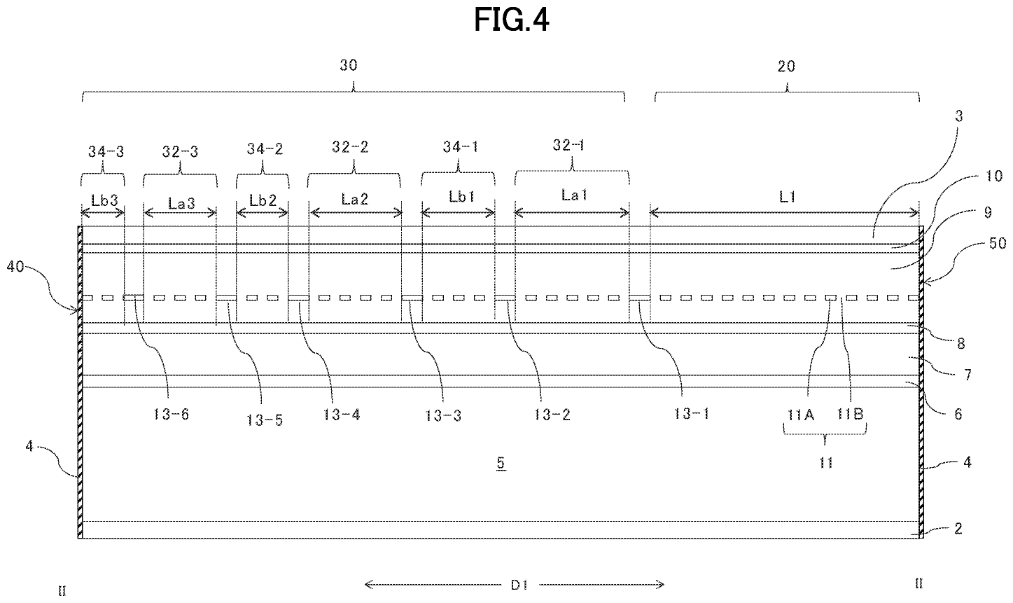

FIG. 4 is a schematic sectional view for illustrating the semiconductor laser 1 according to Modification Example 1 of the first example implementation taken along the line II-II. The first region 20 may have the same structure as that in the first example implementation. The second region 30 may include five secondary phase shift portions 13-2 to 13-6. The phase shift portions 13 may be each a λ/4 phase shift portion. In the same manner as in the first example implementation, the second region 30 may be formed by alternately arranging a π-shift region and an in-phase region in terms of the phase of the diffraction grating layer 11 in the first region 20. The lengths of the first-shift region 32-1, the second π-shift region 32-2, and the third-shift region 32-3 in the first direction D1 may be La1, La2, and La3, respectively. In this case, the lengths differ from one another. The lengths of the first in-phase region 34-1, the second in-phase region 34-2, and a third in-phase region 34-3 in the first direction D1 may be Lb1, Lb2, and Lb3, respectively. In this case, the lengths differ from one another. Further, La1 may be longer than Lb1, La2 may be longer than Lb2, and La3 may be longer than Lb3.

In the same manner as in the first example implementation, reflected waves cancel each other before and after the phase shift portion 13, and hence the normalized coupling coefficient of the entire second region 30 may be κ×(La1−Lb1+La2−Lb2+La3−Lb3). This normalized coupling coefficient may be smaller than the normalized coupling coefficient κL1 of the first region 20. It may be thus possible to increase the intensity of light output from the front facet 40. Further, it may be possible to maintain a single mode oscillation due to low reflection of both facets and a λ/4 shift structure.

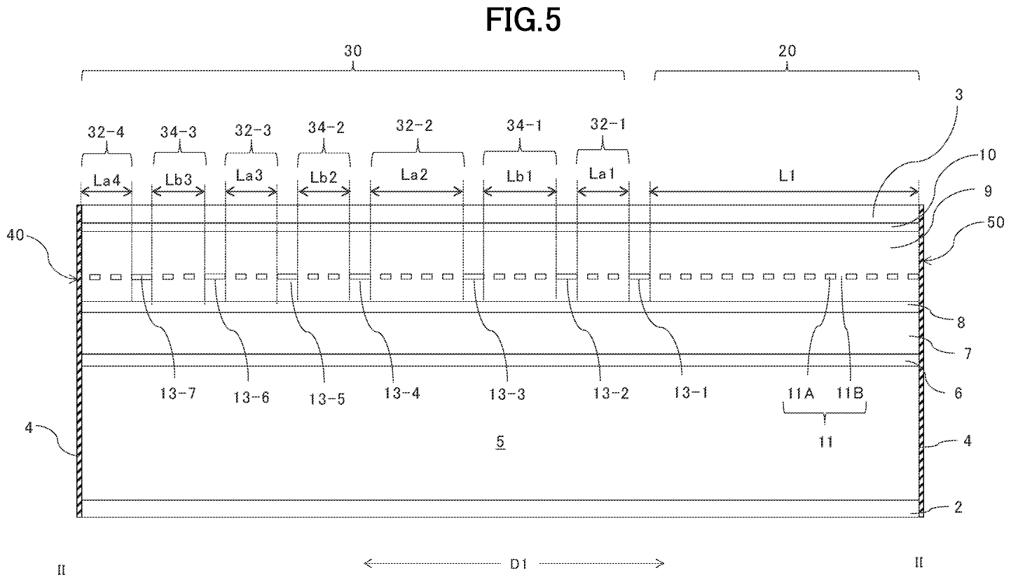

FIG. 5 is a schematic sectional view for illustrating the semiconductor laser 1 according to Modification Example 2 of the first example implementation taken along the line II-II. The first region 20 may have the same structure as that in the first example implementation. The second region 30 may include six secondary phase shift portions 13-2 to 13-7. The phase shift portions 13 may be each a λ/4 phase shift portion. In the same manner as in the first example implementation, the second region 30 may be formed by alternately arranging a π-shift region and an in-phase region in terms of the phase of the diffraction grating layer 11 in the first region 20. The lengths of the first π-shift region 32-1, the second π-shift region 32-2, the third π-shift region 32-3, and a fourth π-shift region 32-4 in the first direction D1 may be La1, La2, La3, and La4, respectively. The lengths of the first in-phase region 34-1, the second in-phase region 34-2, and the third in-phase region 34-3 in the first direction D1 may be Lb1, Lb2, and Lb3, respectively. In this case, La1 may be shorter than Lb1, La2 may be longer than Lb2, and the lengths La3 and Lb3 may be the same. With attention being given only to a vicinity of the phase shift portion 13-2, the length La1 of the first π-shift region 32-1 in which the phase shifts by π may be shorter than the length Lb1 of the first in-phase region 34-1, and hence reflected light beams from the first π-shift region 32-1 with the phase shifting by π do not return to the first region 20. However, when the second region 30 is viewed as a whole, the effects of the present invention may be obtained as long as a total length of regions in which the phase shifts by π may be longer than a total length of regions having the same phase and a difference therebetween may be shorter than the length L1 of the first region 20. Specifically, a total length Lat of regions of the second region 30 in which the phase shifts by π may be La1+La2+La3+La4. A total length Lbt of regions of the second region 30 that may have the same phase (regions in which the phase may be the same as that of the diffraction grating in the first region 20) may be Lb1+Lb2+Lb3. Accordingly, an effective normalized coupling coefficient of the second region 30 may be κ×(Lat−Lbt). In this case, Lat may be larger than Lbt. Further, the normalized coupling coefficient κL1 of the first region 20 may be larger than κ×(Lat−Lbt).

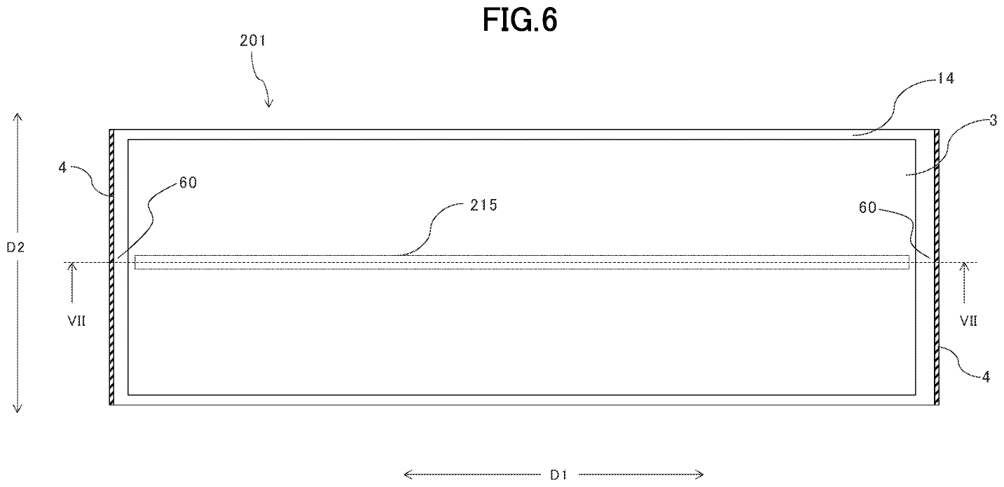

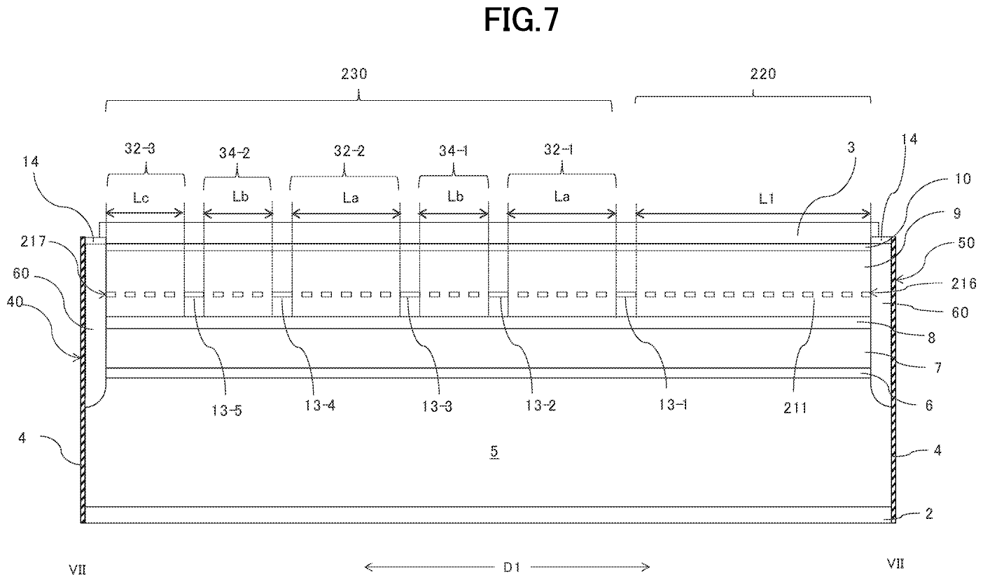

FIG. 6 is a top view for illustrating a semiconductor laser 201 according to a second example implementation of the present invention. FIG. 7 is a schematic sectional view taken along the line VII-VII of FIG. 6. The semiconductor laser 201 differs from the semiconductor laser 1 according to the first example implementation in that window structures 60 may be provided. The window structures 60 may be arranged between a mesa structure 215 and the front facet 40 and back facet 50. The window structure 60 may have a refractive index lower than that of the active layer 7, and may reduce return light beams from the front facet 40 or the back facet 50, thereby achieving a high SMSR yield.

The diffraction grating layer 11 may not be arranged in the window structures 60. A first end portion 216 of the diffraction grating layer 11 may be located at a position at which the window structure 60 on the back side and the mesa structure 215 may be in contact with each other. A second end portion 217 of the diffraction grating layer 11 may be located at a position at which the window structure 60 on the front side and the mesa structure 215 may be in contact with each other. A first region 220 may be defined as extending from the first end portion 216 to the phase shift portion 13-1. Further, a second region 230 may be defined as extending from the phase shift portion 13-1 to the second end portion 217. In the same manner as in FIG. 2, the second region 230 may be formed by alternately arranging each of a plurality of phase shift portions 13, a region in which the phase shifts by π from the phase of the diffraction grating in the first region 220, and a region having the same phase as that of the diffraction grating in the first region 220.

A normalized coupling coefficient of the first region 220 may be κL1, and an effective normalized coupling coefficient of the second region 230 may be κ×(2La−2Lb+Lc). Further, the normalized coupling coefficient of the first region 220 may be larger than the normalized coupling coefficient of the second region.

As described above, in this case, the resonator length not defined as a length between the front facet and the back facet, but may be defined as a length by which the diffraction grating layer 11 is arranged. One end portion of the diffraction grating layer 11 may be a surface at which the diffraction grating layer 11 and the window structure 60 on the back side are in contact with each other, and an end opposite thereto may be a surface at which the diffraction grating layer 11 and the window structure 60 on the front side are in contact with each other. Within a range therebetween, the phase shift portion 13-1 may be arranged on the back side relative to the central portion, thereby achieving both a high power and a single mode oscillation.

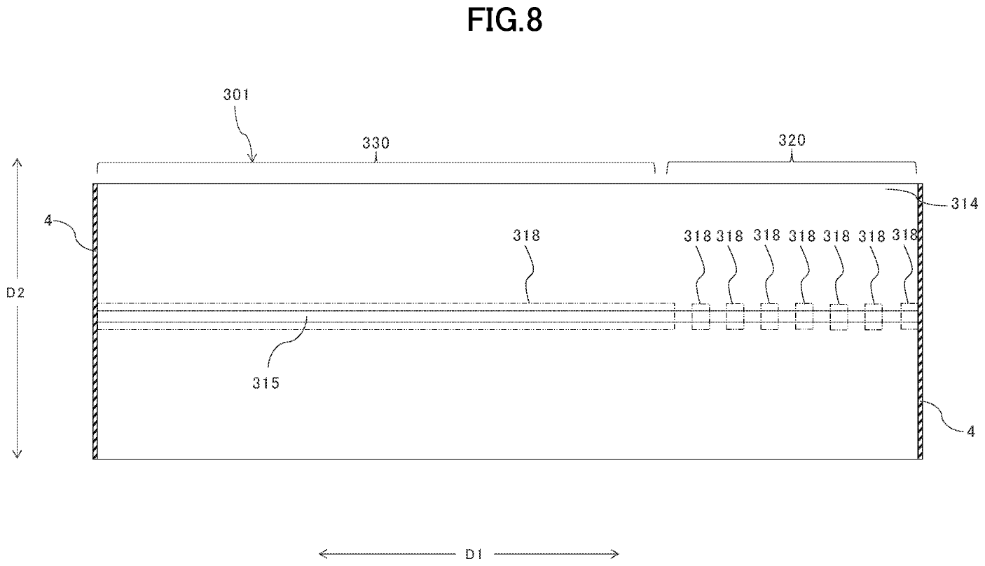

FIG. 8 is a top view for illustrating a semiconductor laser 301 according to a third example implementation of the present invention. The semiconductor laser 301 may have the same structure as that of the semiconductor laser 1 according to the first example implementation except for shapes of through-holes 318. In FIG. 8, a mesa structure 315 may be indicated by the broken lines, and the through-holes 318 may be indicated by the two-dot chain lines. Further, the second electrode 3 is not shown.

The through-holes 318 may be openings formed in an insulating film 314. The through-holes 318 may be not arranged on parts of an upper surface of the mesa structure 315 in a first region 320. In other words, the insulating film 314 may be arranged on the parts of the upper surface of the mesa structure 315 in the first region 320. The through-hole 318 may be formed throughout a second region 330. The second electrode 3 may cover the entire through-holes 318.

As described above in the first example implementation, the normalized coupling coefficient of the first region 320 may be larger than the normalized coupling coefficient of the second region 330. Further, a boundary between the first region 320 and the second region 330, that is, the phase shift portion 13 (not shown in FIG. 8) may be arranged on a back side (right side of FIG. 8) of the semiconductor laser 301 relative to the central portion. For that reason, a photon density of the first region 320 may be lower than a photon density of the second region 330. Consumption of carriers due to stimulated emission increases as the photon density increases, and hence when the first region 320 and the second region 330 have the same injected current density, a carrier density of the first region 320 may be higher than a carrier density of the second region 330. An increase in carrier density may be a factor that degrades characteristics of the semiconductor laser, for example, a relative noise intensity characteristic. The carrier density depends on an amount of the injected current. In view of this, in the third example implementation, in the first region 320, a limitation may be imposed on a region into which the current may be injected, to thereby reduce an increase in carrier density. In order to limit the region into which the current may be injected, there may be provided a structure in which the through-holes 318 in the first region 320 may be not arranged on parts of the upper surface of the mesa structure 315 instead of being formed on the entire upper surface. In other words, the upper surface of the mesa structure 315 in the first region 320 may have an opening portion (through-hole 318) and a non-opening portion (insulating film 314) alternately arranged along the first direction D1. A current may not be injected into a region in which the non-opening portion (insulating film 314) is arranged, thereby being capable of reducing the carrier density of the entire first region 320.

A ratio of the formed opening portions to the entire first region 320 may be preferred to be 60% or less, and may be further preferred to be 50% or less and 20% or more.

The present invention is not limited to the example implementations described above, and various modifications may be made thereto. For example, the configurations described in the example implementations may be replaced by substantially the same configuration, a configuration having the same action and effect, and a configuration which may achieve the same object. Further, the present invention is not limited to a buried type semiconductor laser, and may be applied to a ridge waveguide semiconductor laser. The semiconductor laser may be a CW light source or may be a direct-modulation semiconductor laser.

The present invention achieves both a high power and a single mode oscillation in a DFB laser having a phase shift portion. Those are achieved by each example implementation of the present invention having a structure including the first region having a uniform grating structure, the second region having a plurality of λ/4 shift portions, and the λ/4 phase shift portion connecting the first region and the second region. The second region is formed by alternately arranging the region in which the phase shifts by π from the phase of the diffraction grating in the first region and the region of the diffraction grating having the same phase as that of the diffraction grating in the first region. The total length of the π-shift regions is longer than the total length of the in-phase regions. Further, a difference in length between the π-shift regions and the in-phase regions in the second region is smaller than the length of the first region. Thus, the normalized coupling coefficient of the first region is larger than the normalized coupling coefficient of the second region. In the second region, the lengths of the π-shift regions may be the same, and the lengths of the in-phase regions may be the same. Further, the lengths of the π-shift regions may differ from one another, and the lengths of the in-phase regions may differ from one another. The window structure may be provided between the diffraction grating layer and the both facets. The diffraction grating layer structure may be provided above or below an active layer. The diffraction grating structure may be formed in an optical confinement layer, or may be formed separately from the optical confinement layer. The semiconductor laser may be of a buried type in which a mesa structure is buried by a semiconductor, or may be of a ridge waveguide type in which a mesa structure is not buried by a semiconductor layer. It is also possible to improve characteristics by reducing the carrier density of the first region. In order to reduce the carrier density, an opening ratio of the through-holes to the first region is preferred to be 60% or less, and is further preferred to be 50% or less and 20% or more. The DFB laser according to at least one example implementation of the present invention oscillates wavelength of a 1.3 μm band or a 1.55 μm band. However, another wavelength band may be used.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A semiconductor laser, comprising:
a substrate;
an active layer formed above the substrate;
a diffraction grating layer that includes a primary λ/4 phase shift portion, and includes a first region between a first end portion and the primary λ/4 phase shift portion and a second region between a second end portion on a side opposite to the first end portion and the primary λ/4 phase shift portion;
a first electrode below the substrate in common to the first region and the second region; and
a second electrode above the diffraction grating layer in common to the first region and the second region,
wherein the first region has a diffraction pattern arranged therein, the diffraction pattern having a high reflectance with respect to a light beam having a Bragg wavelength,
wherein the second region includes:
a region in which a π-shift region with a phase shifting by π from a phase of the first region, a secondary λ/4 shift portion, an in-phase region having the same phase as the phase of the first region, and the secondary λ/4 shift portion are arranged toward the second end portion in the stated order; and
the π-shift region arranged on the second end portion side of the region,
wherein a total length of the π-shift region is longer than a total length of the in-phase region in a direction in which the diffraction grating layer extends,
wherein a length of the first region is larger than a difference between the total length of the π-shift region and the total length of the in-phase region in the direction in which the diffraction grating layer extends, and
wherein each of a front facet close to the second end portion and a back facet close to the first end portion has a low-reflection facet coating film formed thereon.

2. The semiconductor laser according to claim 1,
wherein the first region is formed by alternately arranging a first refractive index region and a second refractive index region that have the same length in the direction in which the diffraction grating layer extends,
wherein the π-shift region in the second region is formed by alternately arranging the first refractive index region and the second refractive index region that have the same length as a length of the first refractive index region and the second refractive index region in the first region such that a phase shifts by π from the phase of the first region, and
wherein the in-phase region in the second region is formed by alternately arranging the first refractive index region and the second refractive index region that have the same length as the length of the first refractive index region and the second refractive index region in the first region such that a phase is the same as the phase of the first region.

3. The semiconductor laser according to claim 1, wherein a normalized coupling coefficient of the first region is larger than a normalized coupling coefficient of the second region.

4. The semiconductor laser according to claim 1, wherein a length ratio between the first region and the second region in the direction in which the diffraction grating layer extends is from 3:7 to 9:1.

5. The semiconductor laser according to claim 1,
wherein the second region includes a plurality of regions in each of which the π-shift region, the secondary λ/4 shift portion, the in-phase region, and the secondary λ/4 shift portion are arranged in the stated order,
wherein lengths of the π-shift regions are the same, and
wherein lengths of the in-phase regions are the same.

6. The semiconductor laser according to claim 1,
wherein the second region includes a plurality of regions in each of which the π-shift region, the secondary λ/4 shift portion, the in-phase region, and the secondary λ/4 shift portion are arranged in the stated order,
wherein lengths of the π-shift regions differ from one another, and
wherein lengths of the in-phase regions differ from one another.

7. The semiconductor laser according to claim 1,
wherein the first end portion and the back facet are located at substantially the same position, and
wherein the second end portion and the front facet are located at substantially the same position.

8. The semiconductor laser according to claim 1,
wherein the first end portion and the back facet include a window structure therebetween, and
wherein the second end portion and the front facet include a window structure therebetween.

9. The semiconductor laser according to claim 2, further comprising a cladding layer above the active layer,
wherein the first refractive index region of the diffraction grating layer is a layer having a refractive index higher than a refractive index of the cladding layer, and
wherein the second refractive index region of the diffraction grating layer has the same refractive index as the refractive index of the cladding layer.

10. The semiconductor laser according to claim 1, further comprising a through-hole for injecting a current into the active layer.

11. The semiconductor laser according to claim 10, wherein the through-hole is arranged over the first region and the second region.

12. The semiconductor laser according to claim 10, wherein the through-hole is discretely arranged in the first region.

13. The semiconductor laser according to claim 12, wherein the through-hole is arranged in the first region in a region that is 50% or less and 20% or more of the entire first region in a plan view.
